(19) United States
(12) Patent Application Publication
(10) Pub. No.: US 2004/0126695 A1
(43) Pub. Date: Jul. 1, 2004

(54) Fluorinated polymers

(75) Inventors: Andrew J. Poss, Kenmore, NY (US); Haridasan K. Nair, Williamsville, NY (US); David Nalewajek, West Seneca, NY (US); Michael Van Der Puy, West Seneca, NY (US)

Correspondence Address: HONEYWELL INTERNATIONAL INC., 101 Columbia Road, P.O. Box 2245, Morristown, NJ, 07962-2245, US

(73) Assignee: Honeywell International, Inc., Morristown, NJ

(21) Appl. No.: 10/431,058

(22) Filed: May 7, 2003

Related U.S. Application Data
(60) Provisional application No. 60/378,264, filed on May 7, 2002.

(51) Int. Cl. G03F 7/004; G03C 5/00; G03C 1/492

(52) U.S. Cl. 430/270.1; 430/326; 430/907; 430/271.1

(57) ABSTRACT

Provided are polymers derived from bridged heterocyclic compounds, fluorinated norbornene compounds, fluorinated alkenes, heterocyclic compounds, and combinations of two or more thereof for use in a wide variety of applications, including photoresist compositions. Also provided are methods for producing the monomer compounds for use in the present polymers.

### CROSS-REFERENCE TO RELATED APPLICATION

This application claims the benefit of previously filed U.S. Provisional Application No. 60/378,264, which was filed with the United States Patent and Trademark Office on May 7, 2002.

### FIELD OF INVENTION

The present invention relates generally to polymers derived from fluorinated monomers and the uses of such polymers in lithographic imaging materials, especially photoresist compositions, as well as, dielectric, passivation and insulating materials, light guides, anti-reflective coatings and layers, pellicles, glues and the like. The present invention also relates to novel monomer compounds used for making the polymers of the present invention, and to methods for making such monomer compounds.

### BACKGROUND OF THE INVENTION

Photoresists are organic polymeric materials which find use in a wide variety of applications including use as lithographic imaging materials in semiconductor applications. For example, there is great interest in developing the next generation commercial 157 nm photoresists for a variety of applications in the semiconductor industry. See Chemical and Engineering News, page 23-24, Jul. 15, 2002.

One important property associated with effective photoresists is transparency of the photoresist to light at a given wavelength. Applicants have recognized that although many conventional polymers for optical lithography have demonstrated good performance for use as photoresists at a variety of wavelengths, such polymers nevertheless tend to lack transparency at 157 nm.

For example, U.S. Pat. No. 5,821,036 describes a method of developing positive photoresists and polymer compositions for use therein. While the disclosed polymer compositions are useful in the method of the '036 patent, such compositions tend to be non-transparent and unusable in 157 nm lithographic methods. U.S. Pat. No. 6,124,074 discloses acid catalyzed positive photoresist compositions which tend to be transparent to 193 nm light but not 157 nm light. U.S. Pat. No. 6,365,322 discloses photoresist compositions for deep UV region (100-300 nm) that tend to be non-transparent to 157 nm light.

Prior attempts have been made to produce fluorinated polymers that are substantially transparent to light at wavelengths lower than 194 nm, as described above. See, for example, PCT WO 00/67072 and Hoang et al Macromolecules 2002, 35, 6539-6549, and U.S. Pat. Nos. 6,468,712 and 6,486,282. Although initial screening of these polymers shows promise for transparency at 157 nm, applicants have recognized the need for novel polymers which are not only transparent at 157 nm, but also exhibit resistance to plasma, adhesion to a wide range of substances/surfaces, and exceptional mechanical properties in 157 nm lithography applications. Accordingly, the present invention describes the preparation of novel polymers, as well as novel fluorinated monomers for making such polymers, and methods of using such polymers, including, for example, in 157 nm photoresists.

Each of the documents cited above are herein incorporated in their entirety by reference.

### DESCRIPTION OF THE INVENTION AND PREFERRED EMBODIMENTS

According to one aspect, the present invention provides novel fluorinated polymers that can be used to great advantage in a number of applications including, for example, in lithographic imaging materials, especially photoresist compositions, as well as, dielectric, passivation and insulating materials, light guides, anti-reflective coatings and layers, pellicles and glues. The preferred polymers of the present invention provide transparency and low optical loss in key areas of the ultraviolet (“UV”) and infrared (“IR”) spectrum, are sensitive to actinic radiation, and are resistant to the reactive environment associated with ion etching. Accordingly, such polymers are particularly well suited for use in photoresist applications, as well as other light-sensitive applications. In certain preferred embodiments, the polymers of the present invention comprise one or more repeating units derived from a monomer selected from the group consisting of bicyclic compounds described by Formula I, alkenes described by Formula II, heterocycles described by Formula III and trifluoromethyl-substituted alkynes.

According to another aspect, the present invention provides novel monomer compounds that can be advantageously used to form polymers of the present invention.

According to yet another aspect, the present invention provides novel methods for producing monomer compounds for use in producing the polymers of the present invention.

In certain embodiments, the polymers of the present invention comprise one or more repeating units derived from a monomer described by Formula I, below.

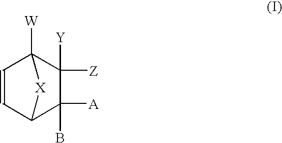

wherein:

X is methylene, difluoromethylene, CHR_{f}, C(R_{f})₂, oxygen or an R-substituted nitrogen, wherein R_{f} is a fluorinated alkyl group having from 1 to about 10 carbon atoms, R is hydrogen, unsubstituted or substituted alkyl, unsubstituted or substituted cycloalkyl, unsubstituted or substituted aryl, or unsubstituted or substituted aralkyl;

W is hydrogen, fluorine, or —(CH₂)ₙ—CO₂R′, wherein n is 0 to about 2, R′ is a C₁-C₅ substituted or unsubstituted alkyl group;

and A, B, Y and Z are independently hydrogen, fluorine, alkyl, alkoxy, aryloxy, alkyl ether, ester or alkyl ester groups, wherein said alkyl, alkoxy, alkyl ether, ester or alkyl ester groups may be unsubstituted or further substituted.

R as an alkyl group may be a straight chain or branched molecule, for example, methyl, ethyl, n-propyl, isopropyl, n-butyl, isobutyl, tert-butyl, n-pentyl, neopentyl, n-hexyl, n-heptyl, n-octyl, 2-ethylhexyl, and the like. Additionally, any of these groups may be substituted with halogen, hydroxyl, alkoxy, aryloxy, alkyl, fluoroalkyl, arylalkyl groups, and the like. In a preferred class of alkyls, R is a fluorinated alkyl, and more preferably a C₁ to C₆ fluorinated alkyl.

R as a cycloalkyl may be, for example, cyclopropyl, cyclobutyl, cyclopentyl, methylcyclopentyl, cylcohexyl, methylcyclohexyl, dimethylcyclohexyl, cycloheptyl, or cyclooctyl. Any of these groups may be substituted with, for example, halogen, hydroxyl, alkoxy, aryloxy, alkyl, fluoroalkyl, arylalkyl groups, and the like. In a preferred class of cycloalkyl, R is a fluorinated cycloalkyl . In a more preferred class of cylcoalkyl, R is a C₅-C₈ fluorinated cycloalkyl.

R as an aryl may be, for example, phenyl, o-tolyl, m-tolyl, p-tolyl, o-xylyl, m-xylyl, p-xylyl, alpha-naphthyl, beta naphthyl, and the like. Any of these groups may be substituted with, for example, halogen, hydroxyl, aryloxy, alkyl, fluoroalkyl, arylalkyl groups, and the like. In a preferred class of aryl, R is a fluorinated aryl.

R as an aralkyl may be, for example, benzyl, 4-methylbenzyl, o-methylbenzyl, p-methylbenzyl, diphenylmethyl, 2-phenylethyl, 2-phenylpropyl, 3-phenylpropyl, and the like. Any of these groups may be substituted with, for example, halogen, hydroxyl, aryloxy, alkyl, fluoroalkyl, arylalkyl groups, and the like. In a preferred class of aralkyl, R is a fluorinated aralkyl.

R′ as a C₁-C₅ substituted or unsubstituted alkyl group may be a straight chain or branched molecule, for example, methyl, ethyl, n-propyl, isopropyl, n-butyl, isobutyl, tert-butyl, n-pentyl, neopentyl, and the like. Additionally, any of these groups may be substituted with halogen, hydroxyl, alkoxy, aryloxy, alkyl, fluoroalkyl, arylalkyl groups, and the like. In a preferred class of alkyls, R is a tert-butyl group.

A, B, Y and/or Z as independently selected alkyl groups may be a straight chain or branched molecules, for example, methyl, ethyl, n-propyl, isopropyl, n-butyl, isobutyl, tert-butyl, n-pentyl, neopentyl, n-hexyl, n-heptyl, n-octyl, 2-ethylhexyl, and the like. Additionally, any of these groups may be substituted with halogen, hydroxyl, alkoxy, aryloxy, alkyl, fluoroalkyl, arylalkyl groups, and the like. In a preferred class of alkyls, A, B, Y and/or Z is a fluorinated alkyl or a hydroxy-substituted fluorinated alkyl, including, for example, trifluoromethyl, and —CH₂C(CF₃)(OH)—CF₃.

A, B, Y and/or Z as independently selected alkoxy or aryloxy groups may be any group of the formula —OR″ wherein R″ is selected independently from, but defined in the same manner above as, R.

A, B, Y and/or Z as independently selected ester or alkyl ester groups may be any group of the formula —(CH₂)ₘ—CO₂′″, wherein m is 0 to about 2, and R′″ is selected independently from, but defined in the same manner above as, R′.

A, B, Y and/or Z as independently selected ether groups may be any group of the formula —R⁴—O—R⁵ wherein R⁴ and R⁵ are selected independently from, but defined in the same manner above as, R. Additionally, any two or more groups selected from A, B, Y and Z may be combined to form cyclic ether substituents.

Examples of Formula I compounds suitable for use in the present invention include bridged heterocyclic compounds, fluorinated norbomene compounds, and the like. As used herein, the term “bridged heterocyclic compound” refers generally to a compound of the Formula IA, below.

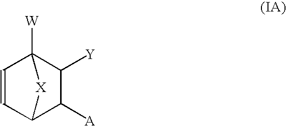

wherein X is oxygen or an R-substituted nitrogen, R is defined as above; and W, Y and A are defined as above. Examples of bridged heterocyclic compounds suitable for use in the present invention include compounds of the formula IA₁, below.

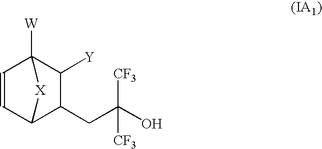

In certain preferred embodiments, the Y group of the compound of formula IA₁ is hydrogen or fluorine. Examples of such preferred compounds include: 7-azabicyclo[2.2.1]hept-5-ene-2-(1,1,1-trifluoro-2-trifluoromethylpropan-2-ol); 7-oxabicyclo[2.2.1]hept-5-ene-2-(1,1,1-trifluoro-2-trifluoromethylpropan-2-ol); 4-fluoro-7-oxabicyclo[2.2.1]hept-5-en-2-(1,1,1-trifluoro-2-trifluoromethylpropan-2-ol); and the like.

Other bridged heterocyclic compounds suitable for use in the present invention include ester-substituted compounds such as 7-oxabicyclo[2.2.1]hept-5-ene-2-(1,1,1-trifluoro-2-trifluoromethylpropan-2-ol)-1-carboxylic acid tert-butyl ester; and the like.

In certain other preferred embodiments, the compounds of Formula I for use in the present invention comprise fluorinated norbomene compounds. As used herein the term “fluorinated norbomene compound” refers generally to a compound of Formula IB, below.

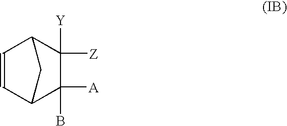

wherein A, B, Y, and Z are defined as above, provided that: (a) at least one of A, B, Y and Z is fluorine or a group comprising fluorine; (b) when Y, Z, and A are all hydrogen, B is not —CH₂C(CF₃)₂OH or —C(CF₃)₂OH; (c) when Y and Z are both hydrogen, and B is trifluoromethyl, A is not —CONH₂; (d) when Z and A are both hydrogen, and Y is —CO₂H, B is not —CH₂F, —CHF₂, —CF₃, —C₂F₅, or n-C₃F₇; (e) when Z and A are both hydrogen, and Y is —CO₂Et, B is not —CF₃, —C₂F₅, n-C₃F₇, or n-C₇F₁₅; (f) when Z and A are both hydrogen, and Y is —CO₂Me, B is not n-C₃F₇; and (g) when Z and A are both hydrogen, and Y is —CH₂OH, B is not —CF₃, —C₂F₅, or n-C₇F,₁₅.

Examples of certain preferred fluorinated norbomene compounds suitable for use in the present invention include compounds described by the formulae IB₁, and IB₂, below.

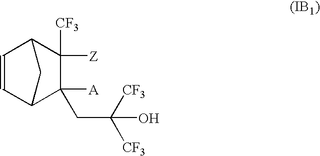

wherein A and Z are defined as above.

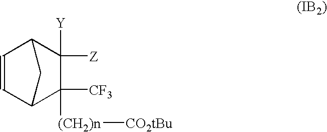

wherein Y and Z are defined as above, provided that when n=1, Y and Z are not both hydrogen.

In certain preferred embodiments, the A and Z groups of formula IB₁ are independently hydrogen, or fluorine. Examples of such preferred compounds include 3-trifluoromethyl-bicyclo[2.2.1]hept-5-ene-2-(1,1,1-trifluoro-2-trifluoromethylpropan-2-ol), 3-fluoro-3-trifluoromethyl-bicyclo[2.2.1]hept-5-ene-2-(1,1,1-trifluoro-2-trifluoromethylpropan-2-ol), 2-fluoro-3-trifluoromethyl-bicyclo[2.2.1]hept-5-ene-2-(1,1,1-trifluoro-2-trifluoromethylpropan-2-ol), 2,3-difluoro-3-trifluoromethyl-bicyclo[2.2.1]hept-5-ene-2-(1,1,1-trifluoro-2-trifluoromethylpropan-2-ol), and the like.

In certain preferred embodiments, the Y and Z groups of formula IB₂ are independently trifluoromethyl, hydrogen, or fluorine. Examples of such preferred compounds include 2-methylpropyl 2,3-(bis-trifluoromethyl)-bicyclo[2.2.1]hept-5-ene-2-carboxylate, 2-methylpropyl 2-trifluoromethyl-bicyclo[2.2.1]hept-5-en-2-yl-acetate, 2-methylpropyl 2-trifluoromethylbicyclo[2.2.1]hept-5-en-2-yl-propionate, 2-methylpropyl 3,3-difluoro-2-trifluoromethyl-bicyclo[2.2.1]hept-5-en-2-yl-acetate, and the like.

Other preferred fluorinated norbornene compounds include cyclic ether compounds such as 2,2-bis(trifluoromethyl)-4-(bicyclo[2.2.1]hept-5-enyl)-1,3-dioxolane, and the like; and trifluoroalkoxynorbornenes of the formula IB₃, below.

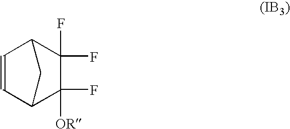

wherein R″ is defined as above.

In certain other embodiments, the polymers of the present invention comprise one or more repeating units derived from a monomer described by Formula II, below.

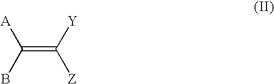

wherein A, B, Y and Z are defined as above. Examples of suitable alkenes of formula II for use in the present invention include those of Formulae IIA, below.

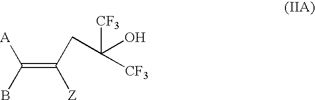

wherein A, B and Z are as defined above.

In certain preferred embodiments, the compounds of formulae IIA comprise A, B, and Z groups wherein A and Z are independently hydrogen or fluorine, and B is hydrogen or trifluoromethyl. Examples of such preferred compounds include 1,1,1,6,6,6-hexafluoro-2-(trifluoromethyl)-hex-4-en-2-ol, 1,1,1,5,6,6,6-heptafluoro-2-(trifluoromethyl)-hex-4-en-2-ol, 1,1,1,4,6,6,6-heptafluoro-2-(trifluoromethyl)-hex-4-en-2-ol, 1,1,1,4,5,6,6,6-octafluoro-2-(trifluoromethyl)-hex-4-en-2-ol, and the like. Other preferred compounds include bis(trifluoromethyl)allylcarbinol, and the like.

Examples of other suitable alkenes of formula II include compounds of formula IIB, below.

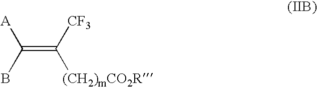

wherein A, B, m and R′″ are defined as above. In certain embodiments of IIB, A and B are preferably, independently hydrogen, fluorine, or trifluoromethyl. Examples of such compounds of formula IIB for use in the present invention include 2-methylpropyl 4,4,4-trifluoro-2-(trifluoromethy)-but-2-enoate, 2-methylpropyl 3-(trifluoromethyl)but-3-enoate, 2-methylpropyl 4-(trifluoromethyl)pent-4-enoate, 2-methylpropyl 4,4-difluoro-3-(trifluoromethyl)but-3-enoate, 2-methylpropyl 5,5-difluoro-4-(trifluoromethyl)pent-4-enoate, and the like.

Examples of other formula II alkenes suitable for use in the present invention include 1,1,1,4,4,4-hexafluorobut-2-ene, 1-(substituted hydroxy)-1,2,2-trifluoroethene, 2,2-bis(trifluoromethyl)-4-methylene-1,3-dioxolane, 1,1,1,4,4,4-hexafluorobut-2-ene, 1-(substituted alkoxy)-1,2,2-trifluoroethene, 2,2-bis(trifluoromethyl)-4-methylene-1,3-dioxolane and the like.

In certain other embodiments, the polymers of the present invention comprise one or more repeating units derived from a heterocyclic monomer described by Formula III, below.

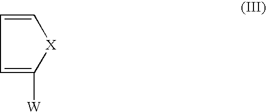

wherein X and W are as defined above. Examples of suitable heterocyclic monomers of formula III include 1-substituted pyrrole, furan, 2-fluorofuran, 2-furoic acid, and the like.

In certain other embodiments, the polymers of the present invention comprise one or more repeating units derived from a trifluoromethyl-substituted alkynes. As used herein the term “trifluoromethyl-substituted alkyne” refers to a linear, cyclic, or bicyclic alkyne compound comprising at least one trifluoromethyl substituent. Suitable trifluoromethyl-substituted alkynes include, for example, 1,1,1,4,4,4-hexafluorobut-2-yne, 2,3-(bis-trifluoromethyl)-bicyclo[2.2.1]hept-2,5-diene, and the like.

In certain embodiments, the polymers of the present invention comprise repeating units that are derived from one or more compounds selected from within only one of the types of monomer compounds, i.e., only bicyclic compounds described by Formula I, only alkenes described by Formula II, only heterocycles described by Formula III, or only trifluoromethyl-substituted alkynes, of the present invention. In such embodiments, the polymer may be a homopolymer, comprising repeating units all derived from the same compound, or the polymer may comprise two or more repeating units derived from two or more different bicyclic compounds described by Formula I, two or more different alkenes described by Formula II, two or more different heterocycles described by Formula III, or two or more different trifluoromethyl-substituted alkynes.

In certain other embodiments, the repeating units of the present polymer are derived from a plurality of compounds of the instant invention, at least two of which are from different types of monomers of the invention. Such compositions may be copolymers, block copolymers, terpolymers, polymers comprising four or more different classes of repeating units, combinations of two or more thereof, and the like.

In yet other embodiments, the polymer of the present invention may include one or more repeating units derived from other monomers, oligomers, or polymer compounds that have been copolymerized with at least one bicyclic compound described by Formula I, alkene described by Formula II, heterocycle described by Formula III, or trifluoromethyl-substituted alkyne, of the present invention. Suitable other monomers, oligomers, and polymer compounds include, for example, ethylenically unsaturated compounds, especially those containing at least one fluorine substituent. Preferred ethylenically unsaturated compounds include those defined by the formulae: CF₃CH═CF₂; CF₃CH═CHF; CF₃CF═CHF; CF₃CF═CH₂; and Rf(CH₂)ₚCX_{f}═C_{f}Y_{f} wherein p is from 0 to about 20; Rf is a perfluoroalkyl group having from about 1 to about 10 carbon atoms, X_{f} and Y_{f} are independently H or F, provided that when Rf is CF₃ and X_{f} is F, Y_{f} must be H.

The polymers of the present invention are prepared by polymerizing one or more compounds selected from the group consisting of bicyclic compounds described by Formula I, alkenes described by Formula II, heterocycles described by Formula III, trifluoromethyl-substituted alkynes, and combinations of two or more thereof, optionally in the presence of any additional monomer compounds to be copolymerized therewith. Any of a wide range of known methods for polymerizing the present compounds can be used according to the present invention. For example, the monomer compounds may be polymerized via exposure to light or heat and/or through the use of a catalyst. In certain embodiments, the polymers of the present invention are prepared by polymerizing a reaction mixture containing the monomer compounds to be polymerized and a single or multicomponent metal catalyst system as disclosed in the published patent application WO 97/33198 (assigned to B.F. Goodrich and incorporated herein by reference.) The polymers of the present invention can also be prepared, for example, using nickel or palladium catalysts as disclosed in Risse, Makromol Chem., Rapid Commun., vol. 12, pages 255-259 (1991), and Hung, Proceedings of SPIE, vol. 4345, pages 385-395 (2001), both of which are incorporated herein by reference. In light of the disclosure herein and the cited documents, those of skill in the art will be readily able to produce polymers of the present invention without undue experimentation.

Uses of the Polymers

The polymers of the present invention have utility in a wide range of applications.

For example, one embodiment of the present invention relates to the use of the present polymers in photoresist compositions. The polymers of the present invention preferably exhibit beneficial transparency characteristics for a range of UV irradiation, most notably at about 157 nanometers, and/or other characteristics that make them particularly suitable for use in photoresist applications.

In certain embodiments, the photoresist compositions of the present invention comprise a polymer of the present invention. In certain other embodiments, the photoresists of the present invention further comprise a solvent and a photoinitiator (for example, a photosensitive acid generator). Any of a wide range of solvents are suitable for use in the photoresist compositions of the present invention. For example, any of the solvents disclosed in published patent application WO 97/33198 may be used herein. Any of a wide range of photoinitiators are suitable for use in the present photoresist compositions. Examples of suitable photoinitiators include those disclosed in published patent application WO 97/33198. In certain embodiments, the photoinitiator is preferably present in an amount of from about 1 to about 100 w/w % to polymer. More preferably the photoinitiator is present in an amount of about 5 to about 50 w/w %.

In certain embodiments, the photoresist compositions of the present invention further comprise a dissolution inhibitor. Any of a wide range of known dissolution inhibitors can be used in the practice of the present invention. For example, t-butyl cholate and the like may be used as a dissolution inhibitors in the present photoresist compositions. Any suitable amount of dissolution inhibitor can be used. Preferably, the dissolution inhibitor is used in an amount of up to about 20 weight % of the photoresist composition.

In certain embodiments, the photoresist compositions of the present invention further comprise a sensitizer capable of sensitizing the photoinitiator to longer wavelengths ranging from mid-UV to visible light. Examples of suitable sensitizers are disclosed in WO 97/33198, and U.S. Pat. Nos. 4,250,053; 4,371,605; and 4,491,628, all of which are incorporated herein by reference.

The photoresist compositions of the present invention can be used to generate a positive tone resist image on a substrate. The present invention provides a method for generating a positive tone resist image on a substrate comprising the steps of (a) coating a substrate with a film comprising a photoresist composition of the present invention, (b) imagewise exposing the film to radiation, and (c) developing the image. The coating, radiating and developing steps can be performed using known techniques. For example, the procedures described in application WO 97/33198 can be adapted for use in the present invention. In light of the disclosure contained herein, those of skill in the art would be readily able to generate a positive resist image according to the methods of the present invention.

The present invention also relates to an integrated circuit assembly, such as an integrated circuit chip, multichip module, or circuit board made by the process and/or using the polymers of the present invention. The integrated circuit assembly preferably comprises a circuit formed on a substrate by the steps of (a) coating a substrate with a film comprising a photoresist composition of the present invention, (b) imagewise exposing the film to radiation, (c) developing the image to expose the substrate, and (d) forming the circuit on the substrate. Any of a wide range of known techniques, including those described in application WO 97/33198, can be adapted for use in the methods of the present invention.

The present polymers also find use as dielectric, passivation and insulating materials, light guides, anti-reflective coatings and layers, pellicles, glues and the like.

Method for Making Monomer Compounds

The present invention further provides efficient methods for producing a wide variety of bicyclic compounds described by Formula I, and alkenes described by Formula II in accordance with the present invention.

For example, according to certain embodiments, the present invention provides for the preparation of bicyclic compounds via the reaction scheme (Scheme 1) shown below.

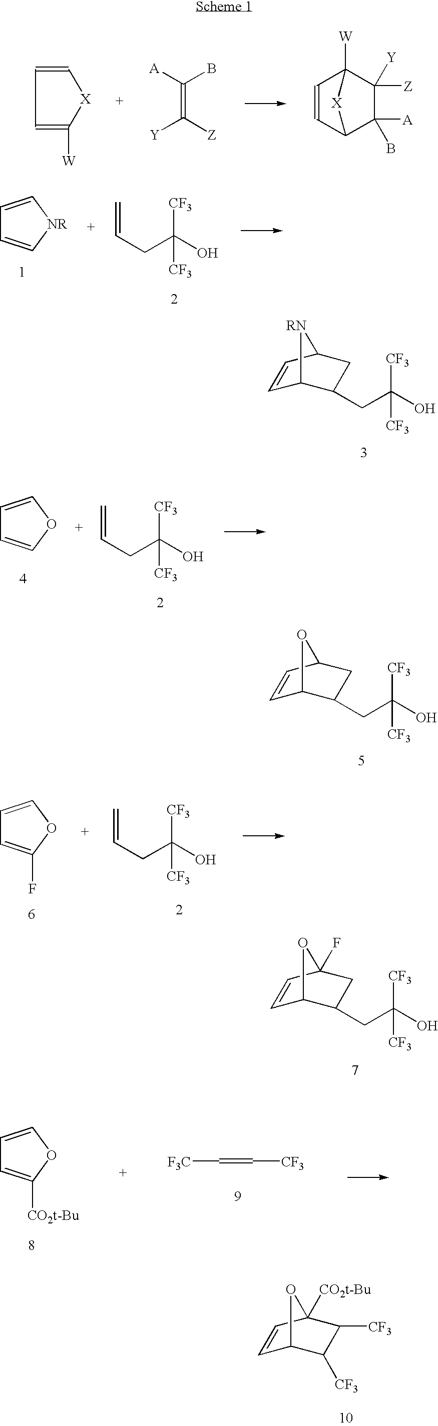

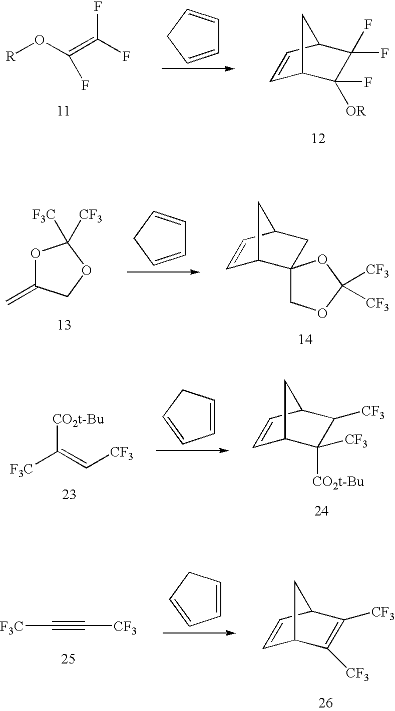

### Scheme 1 Compounds

Compound 1: 1-substituted pyrrole

Compound 2: bis(trifluoromethyl)allylcarbinol

Compound 3: 7-azabicyclo[2.2.1]hept-5-ene-2-(1,1,1-trifluoro-2-trifluoromethylpropan-2-ol)

Compound 4: furan

Compound 5: 7-oxabicyclo[2.2.1]hept-5-ene-2-(1,1,1-trifluoro-2-trifluoromethylpropan-2-ol)

Compound 6: 2-fluorofuran

Compound 7: 4-fluoro-7-oxabicyclo[2.2.1]hept-5-ene-2-(1,1,1-trifluoro-2-trifluoromethylpropan-2-ol)

Compound 8: 2-furoic acid

Compound 9: 1,1,1,4,4,4-hexafluorobut-2-ene

Compound 10: 7-oxabicyclo[2.2.1]hept-5-ene-2-(1,1,1-trifluoro-2-trifluoromethylpropan-2-ol)-1-carboxylic acid tert-butyl ester

Compound 11: 1-(substitutedhydroxy)-1,2,2-trifluoroethene

Compound 12: 3,4,4-trifluoro-3-(substitutedhydroxy)-bicyclo[2.2.1]hept-5-ene

Compound 13: 2,2-bis(trifluoromethyl)-4-methylene- 1,3-dioxolane

Compound 14: 2,2-bis(trifluoromethyl)-4-(bicyclo[2.2.1]hept-5-enyl)-1,3-dioxolane

Compound 23: 2-methylpropyl 4,4,4-trifluoro-2-(trifluoromethy)-but-2-enoate

Compound 24: 2-methylpropyl 2,3-(bis-trifluoromethyl)-bicyclo[2.2.1]hept-5-ene-2-carboxylate

Compound 25: 1,1,1,4,4,4-hexafluorobut-2-yne

Compound 26: 2,3-(bis-trifluoromethyl)-bicyclo[2.2.1]hept-2,5-diene

As shown in scheme 1, a variety of bicyclic compounds of the present invention are prepared by reacting a diene with a reactive alkene or alkyne compound under Diels-Alder conditions to form a bicyclic compound. A variety of dienes for use in the present invention are commercially available, including, for example, Compounds 1, 4, and 8 (available from Aldrich Chemical Co.); or are known in the literature and are obtainable by art-recognized procedures (compound 6 may be produced, for example, by lithiation of 2-bromofuran with n-butyl lithium followed by fluorination with N-fluorobenzenesulfonamide.) In addition, reactive alkenes and alkynes, including compounds 2, 9, 11, 13, 23 and 25 are obtainable by art-recognized procedures (see, for example, Okamoto, J. Poly. Sci. Pt. A. Polym. Chem., 31, 2573 (1993); Hazeldine, J. Chem. Soc., 2504 (1952); Dyatkin, Zh. Org. Khim., 3, 1006 (1967); Hung, J. Fluorine Chem., 52, 159 (1991); Dolbier, J. Org. Chem., 63, 9486 (1998); and Chambers, J. Fluorine Chem., 79, 121 (1996), all of which are incorporated herein by reference.)

Any suitable set of reaction conditions can be used in the practice of the present invention. Temperature, time, and pressure conditions of Diels-Alder reactions are known. The particular set of reaction conditions used in any given reaction will depend on the particular reactants and catalyst used and the time and yield of product desired. Examples of suitable reaction conditions that can be adapted for use herein are disclosed in J. March, Advanced Organic Chemistry, pages 839-856 (Fourth Ed. 1992), incorporated herein by reference.

According to certain other embodiments, the present invention provides for the preparation of alkenes of formula II and fluorine-substituted norbornene compounds via the reaction schemes 2 and 3 shown below.

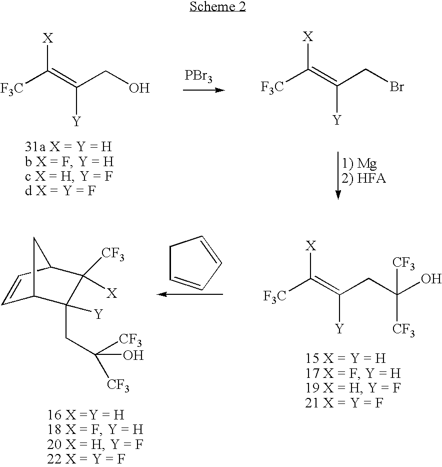

Scheme 2 Compounds

Compound 15: 1,1,1,6,6,6-hexafluoro-2-(trifluoromethyl)-hex-4-en-2-ol

Compound 16: 3-trifluoromethyl-bicyclo[2.2.1]hept-5-ene-2-(1,1,1-trifluoro-2-trifluoromethylpropan-2-ol)

Compound 17: 1,1,1,5,6,6,6-heptafluoro-2-(trifluoromethyl)-hex-4-en-2-ol

Compound 18: 3-fluoro-3-trifluoromethyl-bicyclo[2.2.1]hept-5-ene-2-(1,1,1-trifluoro-2-trifluoromethylpropan-2-ol)

Compound 19: 1,1,1,4,6,6,6-heptafluoro-2-(trifluoromethyl)-hex-4-en-2-ol

Compound 20: 2-fluoro-3-trifluoromethyl-bicyclo[2.2.1]hept-5-ene-2-(1,1,1-trifluoro-2-trifluoromethyllpropan-2-ol)

Compound 21: 1,1,1,4,5,6,6,6-octaafluoro-2-(trifluoromethyl)-hex-4-en-2-ol

Compound 22: 2,3-difluoro-3-trifluoromethyl-bicyclo[2.2.1]hept-5-ene-2-(1,1,1-trifluoro-2-trifluoromethylpropan-2-ol)

As shown in scheme 2, the present method is flexible insofar as it allows for the preparation of any of the compounds described by formulae 15-22, and can be adapted to prepare other, similar compounds of Formulae I and II of the present invention. For example, starting with an alkene compound 31a-d and the initial bromination step shown in Scheme 2, any one or more sequential reaction steps shown in Scheme 2 can be combined according to the present method to make compounds of the formulae 15-22. The present methods encompass any of the novel combinations of sequential steps shown in Scheme 2 to produce any compounds described by formulae 15-22, or other, similar compounds of Formula I and Formula II.

Preferably, the bromination step of Scheme 2 comprises reacting an hydroxyl-substituted alkene with a brominating agent to form a brominated alkene. Syntheses of allyl alcohols, such as those of formulae 31a-d, are described in the U.S. application Ser. No. 60/358,592, which is incorporated herein by reference (and to which priority is claimed).

As used herein, the term “brominating agent” refers generally to any reagent that can be reacted with an hydroxyl-substituted alkene to form a brominated alkene. Any of a number of brominating agents can be used in the method according to the present invention. Examples of suitable brominating agents and conditions for bromination are disclosed in Agnew. Chem. Engl., 36, 980, (1997), incorporated herein by reference. A preferred esterification agent is phosphorus tribromide.

The second step illustrated in Scheme 2 is a Grignard-type reaction. In general, reaction of a brominated alkene with hexafluoroacetone (HFA) under standard Grignard conditions produces trifluorohexenols, such as those of formulae 15, 17, 19, 21, as well as other related compounds of the present invention.

The third step in Scheme 2 is a Diels-Alder reaction. Any suitable set of reaction conditions can be used in step 3. Temperature, time, and pressure conditions of Diels-Alder reactions are known. The particular set of reaction conditions used in any given reaction will depend on the particular reactants and catalyst used and the time and yield of product desired. Examples of suitable reaction conditions that can be adapted for use herein are disclosed in J. March, Advanced Organic Chemistry, pages 839-856 (Fourth Ed. 1992), incorporated herein by reference.

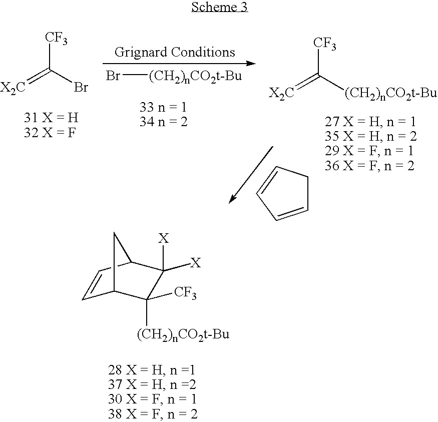

### Scheme 3 Compounds

Compound 27 (n=1): 2-methylpropyl 3-(trifluoromethyl)but-3-enoate

Compound 35 (n=2): 2-methylpropyl 4-(trifluoromethyl)pent-4-enoate

Compound 28 (n=1): 2-methylpropyl 2-trifluoromethyl-bicyclo[2.2.1]hept-5-en-2-yl-acetate

Compound 37 (n=2): 2-methylpropyl 2-trifluoromethylbicyclo[2.2.1]hept-5-en-2-yl-propionate

Compound 29 (n=1): 2-methylpropyl 4,4-difluoro-3-(trifluoromethyl)but-3-enoate

Compound 36 (n=2): 2-methylpropyl 5,5-difluoro-4-(trifluoromethyl)pent-4-enoate

Compound 30 (n=1): 2-methylpropyl 3,3-difluoro-2-trifluoromethyl-bicyclo[2.2.1]hept-5-en-2-yl-acetate

Compound 38 (n=2): 2-methylpropyl 3,3-difluoro-2-trifluoromethyl-bicyclo[2.2.1]hept-5-en-2-yl-propionate

The first step illustrated in Scheme 3 comprises reacting a brominated alkene with a bromoalkylester to produce an alkyl-ester substituted alkene including those of formulae 27, 35, 29 and 36, as well as other compounds of the present invention. Brominated alkenes such as those of formulae 31 and 32 are available commercially (compound 31, for example, can be purchased from SynQuest Labs); and/or are obtainable by art-recognized procedures (compound 32 may be produced, for example, according to procedures described in Henne, J. Am. Chem. Soc., 73, 1042 (1951), which is incorporated herein by reference.) In addition, bromoalkyl esters, such as compounds 33 and 34, are available commercially (for example, from Aldrich).

Any suitable reaction conditions can be used in the first step of Scheme 3. The particular set of reaction conditions used in any given reaction will depend on the particular reactants and catalyst used and the time and yield of product desired. Examples of suitable reaction conditions that can be adapted for use herein are disclosed in Hu, J. Chem. Soc. Comm., page 289 (1994) and Xu, J. Org. Chem., 56, page 7336 (1991), both of which are incorporated herein by reference.

The second step in Scheme 3 is a Diels-Alder reaction. Any suitable set of reaction conditions as disclosed above can be used.

The compounds obtained from any of the aforementioned individual reactions of any of the reaction schemes may be purified by conventional methods known to those skilled in the art. For example, aqueous washes, drying, concentrating under reduced pressure, distillation, and the like may be used.

In light of the above disclosure, those of skill in the art will be readily able to select appropriate reagents and optimize reaction conditions for each of the reaction steps described above without undue experimentation.

### EXAMPLES

In order that the invention may be more readily understood, reference is made to the following examples which are intended to be illustrative of the invention, but are not intended to be limiting in scope.

### Example 1

This example illustrates the preparation of 2-(7-Aza-bicyclo[2.2.1]hept-5-en-2-ylmethyl)-1,1,1,3,3,3-hexafluoro-propan-2-ol according to the present invention.

To an autoclave is charged pyrrole (67 g, 1 mol), allylhexafluoroisopropanol (208 g, 1 mol) and hydroquinone (11 g, 0.1 mol) to form a reaction mixture. The reaction mixture is reacted at 0.1 kbar and 50° C. for 40 h. The product is then separated by distillation from unreacted starting materials to yield 97 g (35%) (bp 100-110° C./0.1 mm) of product.

### Example 2

This example illustrates the preparation of 1,1,1,3,3,3-hexafluoro-2-(7-methyl-7-aza-bicyclo[2.2.1]hept-5-en-2-ylmethyl)-propan-2-ol according to the present invention.

This compound is prepared according to the procedure described in example 1 except that N-methyl pyrrole is substituted for pyrrole. Yield of product is 61 g (21%) mp=70-76° C.

### Example 3

This example illustrates the preparation of 1,1,1,3,3,3-hexafluoro-2-(7-oxa-bicyclo[2.2.1]hept-5-en-2-ylmethyl)-propan-2-ol according to the present invention.

This compound is prepared following the procedure described in Example 1 except that furan is substituted for pyrrole. Yield of product is 117 g (42%) mp 53-59° C.

### Example 4

This example illustrates the preparation of 2,3-Bis-trifluoromethyl-7-oxa-bicyclo[2.2.1]hept-5-en-2-carboxcylic acid tert-butyl ester according to the present invention.

To an autoclave is charged furan (13.6 g, 0.2 mol), 4,4,4-trifluoro-2-trifluoromethyl-but-2-enoic acid tert-butyl ester (10.6 g, 0.2 mol) and hydroquinone (1 g, 9 mmol). The reactor is heated to 100° C. for 96 h to form product. Yield of the product is 7.9 g (12%) with an mp=90-97° C.

### Example 5

This example illustrates the preparation of 2-(2,3-difluoro-3-trifluoromethyl-biciclo[2.2.1]hept-5-en-2-ylmethyl)-1,1,1,3,3,3-hexafluoro-propan-2-ol according to the present invention.

To an autoclave is charged cyclopentadiene (13.2 g, 0.2 mol), 1,1,1,3,4,5,5,5-octafluoro-2-trifluoro-pent-3-en-2-ol (62 g, 0.2 mol), and hydroquinone (0.1 g, 0.9 mmol). The autoclave is heated at 180-190° C. for 40 h to form a product reaction mixture. The product is obtained by extracting the reaction mixture with 10% NaOH solution and washing with hexane. The aqueous layer is acidified with 6N HCl, phase separated, dried and low boiling components removed by evaporation. Yield of product is 15 g (20%) with a mp=68-75° C.

### Example 6

This example illustrates the preparation of 2,3-Bis-trifluoromethyl-bicyclo[2.2.1]hept-5-en-2-carboxylic acid tert-butyl ester according to the present invention.

This compound is prepared by following the procedure described in Example 5 except that 4,4,4-trifluoro-2-trifluoromethyl-but-2-enoic acid tert-butyl ester is substituted for the 1,1,1,3,4,5,5,5-octafluoro-2-trifluoro-pent-3-en-2-ol. The product remaining in the organic phase is isolated by removal of the lower boiling components via distillation. Yield of this reaction is 33.7 g (51%) with a melting point of 80-85° C.

### Example 7

This example illustrates the preparation of 5-tert-Butoxy-5,5,6-trifluoro-bicyclo[2.2.1]hept-2-ene according to the present invention.

This compound is prepared by following the procedure as described in example 6 except that 1-tert-butoxy-1,1,2-trifluoro ethane is used as the dienophile. Yield of product is 16.7 g (38%) with a mp of 35-40° C.

### Example 8

This example illustrates the preparation of 1,1,1,5,6,6,6-heptafluoro-2-trifluoromethyl-hex-4-en-2-ol according to the present invention.

3,4,4,4-Tetrafluoro-but-2-en-1-ol (144 g, 1 mol) is dissolved in 500 mL of ether and treated with PBr₃ (270.7 g, 1 mol). The conversion to product, based on gc analysis is 77%. The crude 4-bromo-1,1,1,2-tetrafluoro-but-2-ene is reacted in 500 mL of ether containing Mg (18.7 g, 0.8 mol). After the formation of the Grignard is complete, the solution is treated with hexafluoroacetone (133 g, 0.8 mol) at 0-5° C. The conversion is 68% based on gc analysis. The product is isolated by distillation. The fraction boiling in the range of 50-55° C./40 mm is used directly in the next step.

### Example 9

This example illustrates the preparation of 1,1,1,3,3,3-hexafluoro-2-(3-fluoro-3-trifluoromethyl-bicyclo-[2.2.1]hept-en-2-ylmethyl)-propan-2-ol according to one embodiment of the present invention.

Cyclopentadiene (13 g, 0.2 mol), the alcohol from example 8 (58 g, 0.2 mol), and hydroquinone (0.1 g, 0.9 mmol) is charged into an autoclave and heated at 170-180° C. for 40 h. The resulting crude product is dissolved in 150 mL of hexane, then extracted with 10% NaOH solution. The aqueous layer is extracted once with an additional 100 mL of hexane. This aqueous layer is acidified with 6N HCl. The organic layer which forms is allowed to phase separate. Low boiling components are removed by distillation to yield the white solid product. Yield: 23.7 g (33%); mp=73-78° C.

### Example 10

This example illustrates the preparation of 1,1,1,3,3,3-hexafluoro-2-(3-fluoro-3-trifluoromethyl-bicyclo-[2.2.1]hept-en-2-ylmethyl)-propan-2-ol according to another embodiment of the present invention.

The compound 4-bromo-1,1,1,2-tetrafluoro-but-2-ene (41.4 g, 0.2 mol), prepared as described in Example 8, is reacted with cyclopentadiene (13.2 g, 0.2 mol) in an autoclave at 180-190° C. for 24 h. The intermediate product, 6-bromo-5-fluoro-5-trifluoromethyl-bicyclo[2.2.1]hept-2-ene was isolated by vacuum distillation. Yield: 41.5 g (76%); bp=70-77° C./0.5 mm.

This intermediate is reacted with Mg (4.86 g, 0.2 mol) in 100 mL of ether. After all of the Mg had reacted, the solution was cooled to ˜5° C. then reacted with hexafluoroacetone (33.2 g, 0.2 mol). After the addition was complete, the solution was warmed to 25° C., stirred for 3 h, hydrolyzed with 3N HCl, and the organic layer dried over MgSO₄. The ether was removed by distillation to yield the product, whose structure was confirmed by gc/ms analysis.

### Example 11

This example illustrates one embodiment of the present invention involving the polymerization of a norbornene monomer of the present invention to form a polymer of the present invention.

To a 50 mL glass via equipped with a Teflon coated stir bar is added a monomer compound 3-trifluoromethyl-bicyclo[2.2.1]hept-5-ene-2-(1,1,1-trifluoro-2-trifluoromethylpropan-2-ol) (10.3 mmol). The monomer compound is stirred at ambient temperature and to the stirred compound is added a catalyst solution. (The catalyst solution is prepared by adding n3-allylpalladium chloride dimer (38 mg, 0.1 mmol) in 5 mL chlorobenzene to silver hexafluoroantimonate (99 mg, 0.3 mmol) in 5 mL chlorobenzene for 30 minutes and then filtering through a micropore filter to remove precipitated silver chloride). The reaction is allowed to run for 36 hours. After this time, the mixture has gelled to form a clear yellow gel. Upon adding the gel to excess methanol, the polymer precipitates as a white powder. The polymer is washed with excess methanol and dried.

What is claimed is:

1. A polymer comprising a repeating unit derived from at least one monomer compound selected from the group consisting of:
(a) bridged heterocyclic compounds of the formula IA: 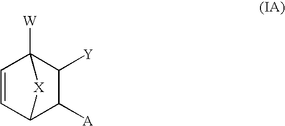
wherein:
X is oxygen or an R-substituted nitrogen;
R is hydrogen, unsubstituted or substituted alkyl, unsubstituted or substituted cycloalkyl, unsubstituted or substituted aryl, or unsubstituted or substitued aralkyl;
W is hydrogen, fluorine, or —(CH₂)ₙ—CO₂R′, wherein n is 0 to about 2, R′ is a C₁-C₅ substituted or unsubstituted alkyl group; and
Y and A are independently hydrogen, fluorine, alkyl, alkoxy, aryloxy, alkyl ether, ester or alkyl ester groups, wherein said alkyl, alkoxy, alkyl ether, ester or alkyl ester groups may be unsubstituted or further substituted;
(b) fluorinated norbornene compounds of the formula IB: 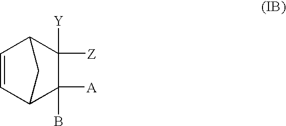
wherein:
Y, Z, A and B are independently hydrogen, fluorine, alkyl, alkoxy, aryloxy, alkyl ether, ester or alkyl ester groups, wherein said alkyl, alkoxy, alkyl ether, ester or alkyl ester groups may be unsubstituted or further substituted;
provided that: (i) at least one of A, B, Y and Z is fluorine or a group comprising fluorine; (ii) when Y, Z, and A are all hydrogen, B is not —CH₂C(CF₃)₂OH or —C(CF₃)₂OH; (iii) when Y and Z are both hydrogen, and B is trifluoromethyl, A is not —CONH₂; (iv) when Z and A are both hydrogen, and Y is —CO₂H, B is not —CH₂F, —CHF₂, —CF₃, —C₂F₅, or n-C₃F₇; (v) when Z and A are both hydrogen, and Y is —CO₂Et, B is not —CF₃, —C₂F₅, n-C₃F₇, or n-C₇F₁₅; (vi) when Z and A are both hydrogen, and Y is —CO₂Me, B is not n-C₃F₇; and (vii) when Z and A are both hydrogen, and Y is —CH₂OH, B is not —CF₃, —C₂F₅, or n-C₇F₁₅;
(c) alkenes of the formulae IIA and IIB: 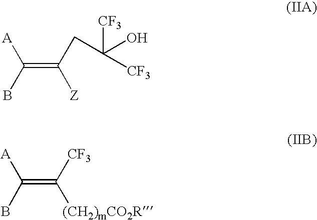
wherein:
Z, A and B are independently hydrogen, fluorine, alkyl, alkoxy, aryloxy, alkyl ether, ester or alkyl ester groups, wherein said alkyl, alkoxy, alkyl ether, ester or alkyl ester groups may be unsubstituted or further substituted;
m is about zero to about 2; and
R′″ is a C₁-C₅ substituted or unsubstituted alkyl group;
(d) heterocyclic compounds of the formula III: 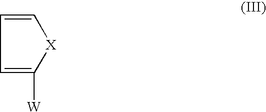
wherein:
X is methylene, oxygen or an R-substituted nitrogen, wherein R is hydrogen, unsubstituted or substituted alkyl, unsubstituted or substituted cycloalkyl, unsubstituted or substituted aryl, or unsubstituted or substitued aralkyl; and
W is hydrogen, fluorine, or —(CH₂)ₙ—CO₂R′, wherein n is 0 to about 2, R′ is a C₁-C₅ substituted or unsubstituted alkyl group; and
(e) combinations of two or more thereof.

2. The polymer of claim 1 comprising at least one repeating unit derived from a bridged heterocyclic compound of formula IA.

3. The polymer of claim 2 wherein said repeating unit is derived from a bridged heterocyclic compound of formula IA wherein A is —CH₂C(CF₃)₂OH.

4. The polymer of claim 3 wherein said bridged heterocyclic compound is selected from the group consisting of 7-azabicyclo[2.2.1]hept-5-ene-2-(1,1,1-trifluoro-2-trifluoromethylpropan-2-ol); 7-oxabicyclo[2.2.1]hept-5-ene-2-(1,1,1-trifluoro-2-trifluoromethylpropan-2-ol); 4-fluoro-7-oxabicyclo[2.2.1]hept-5-en-2-(1,1,1-trifluoro-2-trifluoromethylpropan-2-ol); and mixtures of two or more thereof.

5. The polymer of claim 1 comprising at least one repeating unit derived from a fluorinated norbornene compound of formula IB.

6. The polymer of claim 5 wherein said repeating unit is derived from a fluorinated norbornene compound of formula IB selected from the group consisting of compounds of formula IB wherein: (a) Y is trifluoromethyl and B is —CH₂C(CF₃)₂OH; (b) A is trifluoromethyl, B is —(CH₂)ₙCO₂tBu, and n is about 0 to about 2; (c) Y, Z, and A are fluorine, B is —OR″ , and R″ is defined as R in claim 1; and (d) combinations of two or more thereof.

7. The polymer according to claim 6 wherein said repeating unit is derived from a fluorinated norbornene compound selected from the group consisting of: 3-trifluoromethyl-bicyclo[2.2.1]hept-5-ene-2-(1,1,1-trifluoro-2-trifluoromethylpropan-2-ol), 3-fluoro-3-trifluoromethyl-bicyclo[2.2.1]hept-5-ene-2-(1,1,1-trifluoro-2-trifluoromethylpropan-2-ol); 2-fluoro-3-trifluoromethyl-bicyclo[2.2.1]hept-5-ene-2-(1,1,1-trifluoro-2-trifluoromethylpropan-2-ol), 2,3-difluoro-3-trifluoromethyl-bicyclo[2.2.1]hept-5-ene-2-(1,1,1-trifluoro-2-trifluoromethylpropan-2-ol), 2-methylpropyl 2,3-(bis-trifluoromethyl)-bicyclo[2.2.1]hept-5-ene-2-carboxylate, 2-methylpropyl 2-trifluoromethyl-bicyclo[2.2.1]hept-5-en-2-yl-acetate, 2-methylpropyl 2-trifluoromethylbicyclo[2.2.1]hept-5-en-2-yl-propionate, 2-methylpropyl 3,3-difluoro-2-trifluoromethyl-bicyclo[2.2.1]hept-5-en-2-yl-acetate, and combinations of two or more thereof.

8. The polymer of claim 1 comprising at least one repeating unit derived from an alkene of formula IIA or IIB.

9. The polymer according to claim 8 wherein said at least one alkene compound is selected from the group consisting of 1,1,1,6,6,6-hexafluoro-2-(trifluoromethyl)-hex-4-en-2-ol, 1,1,1,5,6,6,6-heptafluoro-2-(trifluoromethyl)-hex-4-en-2-ol, 1,1,1,4,6,6,6-heptafluoro-2-(trifluoromethyl)-hex-4-en-2-ol, 1,1,1,4,5,6,6,6-octafluoro-2-(trifluoromethyl)-hex-4-en-2-ol, 2-methylpropyl 4,4,4-trifluoro-2-(trifluoromethy)-but-2-enoate, 2-methylpropyl 3-(trifluoromethyl)but-3-enoate, 2-methylpropyl 4-(trifluoromethyl)pent-4-enoate, 2-methylpropyl 4,4-difluoro-3-(trifluoromethyl)but-3-enoate, 2-methylpropyl 5,5-difluoro-4-(trifluoromethyl)pent-4-enoate, and combinations of two or more thereof.

10. The polymer according to claim 1 wherein said monomer compound is selected from the group consisting of 7-azabicyclo[2.2.1]hept-5-ene-2-(1,1,1-trifluoro-2-trifluoromethylpropan-2-ol); 7-oxabicyclo[2.2.1]hept-5-ene-2-(1,1,1-trifluoro-2-trifluoromethylpropan-2-ol); 4-fluoro-7-oxabicyclo[2.2.1]hept-5-en-2-(1,1,1-trifluoro-2- trifluoromethylpropan-2-ol); 3-trifluoromethyl-bicyclo[2.2.1]hept-5-ene-2-(1,1,1-trifluoro-2-trifluoromethylpropan-2-ol); 3-fluoro-3-trifluoromethyl-bicyclo[2.2.1]hept-5-ene-2-(1,1,1-trifluoro-2-trifluoromethylpropan-2-ol); 2-fluoro-3-trifluoromethyl-bicyclo[2.2.1]hept-5-ene-2-(1,1,1-trifluoro-2-trifluoromethylpropan-2-ol); 2,3-difluoro-3-trifluoromethyl-bicyclo[2.2.1]hept-5 -ene-2-(1,1,1-trifluoro-2-trifluoromethylpropan-2-ol); 2-methylpropyl 2,3-(bis-trifluoromethyl)-bicyclo[2.2.1]hept-5-ene-2-carboxylate; 2-methylpropyl 2-trifluoromethyl-bicyclo[2.2.1]hept-5-en-2-yl-acetate; 2-methylpropyl 2-trifluoromethylbicyclo[2.2.1]hept-5-en-2-yl-propionate; 2-methylpropyl 3,3-difluoro-2-trifluoromethyl-bicyclo[2.2.1]hept-5-en-2-yl-acetate; 1,1,1,6,6,6-hexafluoro-2-(trifluoromethyl)-hex-4-en-2-ol; 1,1,1,5,6,6,6-heptafluoro-2-(trifluoromethyl)-hex-4-en-2-ol; 1,1,1,4,6,6,6-heptafluoro-2-(trifluoromethyl)-hex-4-en-2-ol; 1,1,1,4,5,6,6,6-octafluoro-2-(trifluoromethyl)-hex-4-en-2-ol; 2-methylpropyl 4,4,4-trifluoro-2-(trifluoromethy)-but-2-enoate; 2-methylpropyl 3-(trifluoromethyl)but-3-enoate; 2-methylpropyl 4-(trifluoromethyl)pent-4-enoate; 2-methylpropyl 4,4-difluoro-3-(trifluoromethyl)but-3-enoate; 2-methylpropyl 5,5-difluoro-4-(trifluoromethyl)pent-4-enoate; 2,2-bis(trifluoromethyl)-4-(bicyclo[2.2.1]hept-5-enyl)-1,3-dioxolane; 1,1,1,4,4,4-hexafluorobut-2-ene, 1-(substitutedhydroxy)-1,2,2-trifluoroethene; 2,2-bis(trifluoromethyl)-4-methylene-1,3-dioxolane; 1,1,1,4,4,4-hexafluorobut-2-yne; 2,3-(bis-trifluoromethyl)-bicyclo[2.2.1]hept-2,5-diene; and mixtures of two or more thereof.

11. The polymer according to claim 1, further comprising repeating units derived from an ethylenically unsaturated compounds selected from the group consisting of CF₃CH═CF₂, CF₃CH═CHF, CF₃CF═CHF, CF₃CF═CH₂, compounds of the formula Rf(CH₂)ₙCXf═CXfYf wherein Rf is a perfluoroalkyl group having from about 1 to about 10 carbon atoms, Xf and Yf are independently H or F, provided that when Rf is CF₃ and Xf is F, Yf must be H, and mixtures of two or more thereof.

12. A photoresist composition comprising a polymer according to claim 1.

13. The photoresist composition of claim 12 further comprising a solvent and a photoinitiator.

14. The photoresist composition of claim 12 further comprising a dissolution inhibitor.

15. The photoresist composition of claim 12 further comprising a sensitizer.

16. A method for generating a positive tone resist image on a substrate comprising the steps of (a) coating a substrate with a film comprising a photoresist composition of claim 12, (b) exposing the film to radiation, and (c) developing the image.

17. An integrated circuit assembly comprising a circuit formed by the steps of: (a) coating a substrate with a film comprising a photoresist composition of claim 12, (b) exposing the film to radiation, (c) developing the image to expose the substrate, and (d) forming a circuit on the substrate.

18. A light guide comprising a polymer according to claim 1.

19. An anti-reflective coating comprising a polymer according to claim 1.

20. A pellicle comprising a polymer according to claim 1.

21. A glue comprising a polymer according to claim 1.

22. A method of making a compound selected from the group consisting of fluorinated norbornene compounds of formula IB and alkenes of formula IIA comprising:
reacting a hydroxyl-substituted alkene with a brominating agent to form a brominated alkene; and
converting said brominated alkene to a compound selected from the group consisting of fluorinated norbornene compounds of formula IB and alkenes of formula IIA.

23. The method of claim 22 wherein said converting step comprises reacting said brominated alkene with hexafluoroacetone under Grignard conditions to produce an alkene of formula IIA.

24. The method of claim 23 wherein said converting step further comprises reacting said alkene of formula IIA with cyclopentadiene under Diels-Alder conditions to produce a fluorinated norbornene compound of formula IB.

25. A method of making a compound of formula IB comprising reacting a brominated alkene with a bromoalkylester under Grignard conditions to produce an alkyl-ester-substituted alkene and reacting said alkyl-ester-substituted alkene with cyclopentadiene under Diels-Alder conditions to produce a compound of formula IB.

26. A compound selected from the group consisting of:
(a) bridged heterocyclic compounds of the formula IA: 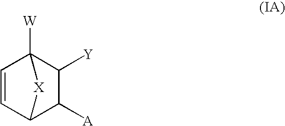
wherein:
X is oxygen or an R-substituted nitrogen;
R is hydrogen, unsubstituted or substituted alkyl, unsubstituted or substituted cycloalkyl, unsubstituted or substituted aryl, or unsubstituted or substitued aralkyl;
W is hydrogen, fluorine, or —(CH₂)ₙ—CO₂R′, wherein n is 0 to about 2, R′ is a C₁-C₅ substituted or unsubstituted alkyl group; and
Y and A are independently hydrogen, fluorine, alkyl, alkoxy, aryloxy, alkyl ether, ester or alkyl ester groups, wherein said alkyl, alkoxy, alkyl ether, ester or alkyl ester groups may be unsubstituted or further substituted; and
(b) fluorinated norbornene compounds of the formula IB: 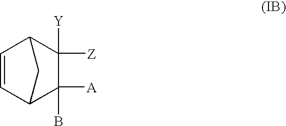
wherein:
Y, Z, A and B are independently hydrogen, fluorine, alkyl, alkoxy, aryloxy, alkyl ether, ester or alkyl ester groups, wherein said alkyl, alkoxy, alkyl ether, ester or alkyl ester groups may be unsubstituted or further substituted;
provided that: (i) at least one of A, B, Y and Z is fluorine or a group comprising fluorine; (ii) when Y, Z, and A are all hydrogen, B is not —CH₂C(CF₃)₂OH or —C(CF₃)₂OH; (iii) when Y and Z are both hydrogen, and B is trifluoromethyl, A is not —CONH₂; (iv) when Z and A are both hydrogen, and Y is —CO₂H, B is not —CH₂F, —CHF₂, —CF₃, —C₂F₅, or n-C₃F₇; (v) when Z and A are both hydrogen, and Y is —CO₂Et, B is not —CF₃, —C₂F₅, n-C₃F₇, or n-C₇F₁₅; (vi) when Z and A are both hydrogen, and Y is —CO₂Me, B is not n-C₃F₇; and (vii) when Z and A are both hydrogen, and Y is —CH₂OH, B is not —CF₃, —C₂F₅, or n-C₇F₁₅.

27. The compound of claim 26 comprising a bridged heterocyclic compound of formula IA.

28. The compound of claim 27 wherein A is —CH₂C(CF₃)₂OH.

29. The compound of claim 27 selected from the group consisting of 7-azabicyclo[2.2.1]hept-5-ene-2-(1,1,1-trifluoro-2-trifluoromethylpropan-2-ol); 7-oxabicyclo[2.2.1]hept-5-ene-2-(1,1,1-trifluoro-2-trifluoromethylpropan-2-ol); 4-fluoro-7-oxabicyclo[2.2.1]hept-5-en-2-(1,1,1-trifluoro-2-trifluoromethylpropan-2-ol); and mixtures of two or more thereof.

30. The compound of claim 26 comprising a fluorinated norbornene compound of formula IB.

31. The compound of claim 30 wherein said fluorinated norbornene is selected from the group consisting of compounds of formula IB wherein: (a) Y is trifluoromethyl and B is —CH₂C(CF₃)₂OH; (b) A is trifluoromethyl, B is —(CH₂)ₙCO₂tBu, and n is about 0 to about 2; and (c) Y, Z, and A are fluorine, B is —OR″, and R″ is defined as R in claim 1.

32. The compound of claim 31 selected from the group consisting of: 3-trifluoromethyl-bicyclo[2.2.1]hept-5-ene-2-(1,1,1-trifluoro-2-trifluoromethylpropan-2-ol), 3-fluoro-3-trifluoromethyl-bicyclo[2.2.1]hept-5-ene-2-(1,1,1-trifluoro-2-trifluoromethylpropan-2-ol), 2-fluoro-3-trifluoromethyl-bicyclo[2.2.1]hept-5-ene-2-(1,1,1-trifluoro-2-trifluoromethylpropan-2-ol), 2,3-difluoro-3-trifluoromethyl-bicyclo[2.2.1]hept-5-ene-2-(1,1,1-trifluoro-2-trifluoromethylpropan-2-ol), 2-methylpropyl 2,3-(bis-trifluoromethyl)-bicyclo[2.2.1]hept-5-ene-2-carboxylate, 2-methylpropyl 2-trifluoromethyl-bicyclo[2.2.1]hept-5-en-2-yl-acetate, 2-methylpropyl 2-trifluoromethylbicyclo[2.2.1]hept-5-en-2-yl-propionate, and 2-methylpropyl 3,3-difluoro-2-trifluoromethyl-bicyclo[2.2.1]hept-5-en-2-yl-acetate.
